(19) United States
(12) Patent Application Publication
(10) Pub. No.: US 2024/0402278 A1
(43) Pub. Date: Dec. 5, 2024

(54) METHOD AND DEVICE FOR ON-DIE IMPEDANCE CALIBRATION

(71) Applicant: STMicroelectronics International N.V., Geneva (CH)

(72) Inventors: Ravinder Kumar KUMAR, Ambala City (IN); Saiyid Mohammad Irshad RIZVI, New Delhi (IN)

(73) Assignee: STMicroelectronics International N.V., Geneva (CH)

(21) Appl. No.: 18/677,437

(22) Filed: May 29, 2024

Related U.S. Application Data
(60) Provisional application No. 63/505,327, filed on May 31, 2023.

(51) Int. Cl. G01R 35/00; G01R 19/10; G01R 27/02

(52) U.S. Cl. CPC G01R 35/005; G01R 19/10; G01R 27/02

(57) ABSTRACT

A test circuit is configured to test and calibrate an impedance of a driver of an integrated circuit. Testing the impedance includes driving first and second currents through the driver via a first contact pad and a ground metallization of the integrated circuit. Testing the impedance includes measuring the voltage at a test metalization while driving the first and second current while the test metalization is successively coupled to the first contact pad and the ground metallization while driving the first and second test currents.

### BACKGROUND

### Technical Field

The present disclosure generally relates to integrated circuits, and more particularly to integrated circuits with high-speed physical layers.

### Description of the Related Art

Integrated circuits often provide data to circuits, systems, or components external to the integrated circuits. One way in which integrated circuits can provide data to circuits, systems, or components external to the integrated circuits is via a high-speed physical layer. High-speed point-to-point communications are broadly used in physical layer (PHY) protocols and Serializer/Deserializer (SerDes) systems. In some video-based applications, such as displays, serial data is transmitted by display ports with a low voltage supply. The high-speed serial data transmission is based on a low voltage differential signaling, which results in a low differential voltage swing at the output of the transmitter. A voltage driver is used to receive the input voltage from the low voltage supply and generate the output voltage at the output ports of the transmitter with an acceptable differential voltage swing specification.

In general, high-speed serial data transmission is based on differential signals between two output contacts. In some video applications, the two output contacts are a display positive (Dp) port and a display negative (Dn) port. The display positive and negative ports are coupled to a load of a receiver. To achieve an optimum transmission efficiency, the impedance line of the transmitter is matched with the impedance of the load of the receiver. A positive signal transmitted by the positive port is approximately in opposite phase with a negative signal transmitted by the negative port. In this differential condition, the data is transmitted by a voltage difference between the positive and negative signals. The low voltage differential signaling allows high-speed data transmission with a rate of about 155 Mbps to 20 Gbps. The transmission data rate may be limited by impedance mismatch between the transmitter and the load. The impedance mismatch may cause reflection waves and mode conversion, which results in degrading the differential signaling.

### BRIEF SUMMARY

Embodiments of the present disclosure provide a method and system that enable precise impedance matching for an integrated circuit implementing a physical layer protocol. The integrated circuit includes a driver that outputs data via two contact pads of the integrated circuit. The driver includes an internal resistance that plays a large role in the overall impedance of the driver. The driver also includes supply and ground metallizations that connect NMOS and PMOS transistors of the driver to the supply and ground of the integrated circuit. Supply and ground metallizations are present prior to packaging, but are inaccessible after packaging. The integrated circuit also includes a test metallization that is present prior to packaging, but is inaccessible for electrical connection after packaging. Embodiments of the present disclosure utilize the test metallization in order to enable measurement and trimming of the impedance of the driver.

In one embodiment, prior to packaging the integrated circuit, a test circuit interfaces with the integrated circuit. The test circuit drives a first current through the driver via the first and ground metallization. The test circuit measures, via the test metallization, a first voltage difference between the first contact pad and ground metallization while driving the first test current. The test circuit then drives a second test current through the driver and measures, via the test metallization, a second voltage difference between the first contact pad and ground metallization while driving the second test current. The test circuit then calculates the impedance of the driver based on the first and second voltage drops.

Because the two voltage drops are measured via the internal test metallization for the two different tests currents, the calculated impedance is independent from any internal impedance of the test circuitry. If the calculated impedance does not match a reference impedance, then the test circuit can adjust the internal resistance of the driver and again calculate the impedance. This process can be repeated until the impedance of the driver has been matched to the reference impedance. The integrated circuit can then be packaged.

In one embodiment, while driving the first test current, the test circuit closes a first switch of the integrated circuit, thereby coupling the test metallization to a first of the two contact pads. The test circuit then measures a first test voltage at the test metallization while the first switch is closed and the first test current is present. The test circuit then opens the first switch and closes a second switch of the integrated circuit, thereby coupling the test metallization to aground metallization. The test circuit then measures a second voltage at the test metallization. The test circuit then calculates the first voltage drop as the difference between the first and second test voltages.

In one embodiment, while driving the second test current, the test circuit closes the first switch and opens the second switch, thereby coupling the test metallization to the first contact pad. The test circuit then measures a third test voltage at the test metallization while the first switch is closed and the second test current is present. The test circuit then opens the first switch and closes the second switch, thereby coupling the test metallization to aground metallization. The test circuit then measures a fourth voltage at the test metallization. The test circuit then calculates the second voltage drop as the difference between the third and fourth test voltages.

In one embodiment, after calculating the first and second voltage drops, the test circuit calculates the impedance of the driver. The test circuit can calculate the impedance of the driver by calculating the difference between the first and second voltage drops and then dividing the difference between the first and second voltage drops by the difference between the first and second tests currents. This also eliminates the error due to the contact probe impedances that is significant amount of target driver impedance. Contact probe error get eliminates as impedance is calculated by taking difference of two voltage and difference of two currents. This provides an accurate calculation or measurement of the impedance of the driver.

In one embodiment, a method includes driving, with a test circuit external to an integrated circuit, a first test current I1 from a first contact pad of the integrated circuit through a driver of the integrated circuit to ground metallization of the integrated circuit. The method includes measuring, with the test circuit, a first voltage drop VD1 at a test metalization of the integrated circuit while driving the first current I1 and driving, with the test circuit, a second test current I2 different from the first test current I1 from the first contact pad through a driver to the ground metallization. The method includes measuring, with the test circuit, a second voltage drop VD2 at the test metalization while driving the second test current I2 and calculating an impedance Z of the driver based on the first voltage difference VD1 and the second voltage difference VD2.

In one embodiment, an integrated circuit package includes an integrated circuit die. The integrated circuit includes a first contact pad, a second contact pad, and a driver and configured to drive data from the integrated circuit via the first contact pad and the and including a resistive path coupled between the first contact pad and ground. The integrated circuit includes a test metalization, a first switch coupled between the first contact pad and the test metalization, and a second switch coupled between the ground metallization and the test metalization.

In one embodiment, a method includes applying a first driver calibration code from a test circuit to an integrated circuit external to the integrated circuit and measuring, with the test circuit, an impedance of a driver of the integrated circuit. Measuring the impedance of the driver includes driving a first test current through the driver between a first contact pad and ground metallization of the integrated circuit, coupling a test metalization of the integrated circuit to the first contact pad by closing a first switch of the integrated circuit while driving the first test current, and measuring a first test voltage at the test metalization while driving the first test current while the first switch is closed.

In one embodiment, a test circuit includes a first lead, a second lead, a third lead, and a control circuit. The control circuit is configured to drive a first test current between the first lead and the second lead through a driver of an integrated circuit via a first contact pad of the integrated circuit coupled to the first lead and a ground metallization of the integrated circuit coupled to the second lead. The control circuit is configured to couple a test metalization of the integrated circuit to the first contact pad by closing a first switch of the integrated circuit while driving the first test current. The control circuit is configured to measure, with the third lead, a first test voltage at the test metalization while driving the first test current while the first switch is closed. The control circuit is configured to calculate an impedance of the driver based on the first test voltage.

### BRIEF DESCRIPTION OF THE SEVERAL VIEWS OF THE DRAWINGS

FIG. 1 is a block diagram of a system including an integrated circuit and a test circuit, according to one embodiment.

FIG. 2 is a schematic diagram of a driver of an integrated circuit, according to one embodiment.

FIG. 3 is a simplified schematic diagram of a system including an integrated circuits and a test circuit, according to one embodiment.

FIG. 4A is an illustration of a wafer, according to one embodiment.

FIG. 4B is an enlarged view of a portion of the wafer of FIG. 3A, according to one embodiment.

FIG. 5 is a cross-sectional view of an integrated circuit package, according to one embodiment.

FIG. 6 is a flow diagram of a method for calibrating a driver of an integrated circuit, according to one embodiment.

FIG. 7 is a flow diagram of a method for calibrating a driver of an integrated circuit, according to one embodiment.

### DETAILED DESCRIPTION

In the following description, certain specific details are set forth in order to provide a thorough understanding of various disclosed embodiments. However, one skilled in the relevant art will recognize that embodiments may be practiced without one or more of these specific details, or with other methods, components, materials, etc. In other instances, well-known systems, components, and circuitry associated with integrated circuits have not been shown or described in detail, to avoid unnecessarily obscuring descriptions of the embodiments.

Unless the context requires otherwise, throughout the specification and claims which follow, the word “comprise” and variations thereof, such as, “comprises” and “comprising” are to be construed in an open, inclusive sense, that is as “including, but not limited to.” Further, the terms “first,” “second,” and similar indicators of sequence are to be construed as interchangeable unless the context clearly dictates otherwise.

Reference throughout this specification to “one embodiment” or “an embodiment” means that a particular feature, structure or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its broadest sense, that is as meaning “and/or” unless the content clearly dictates otherwise.

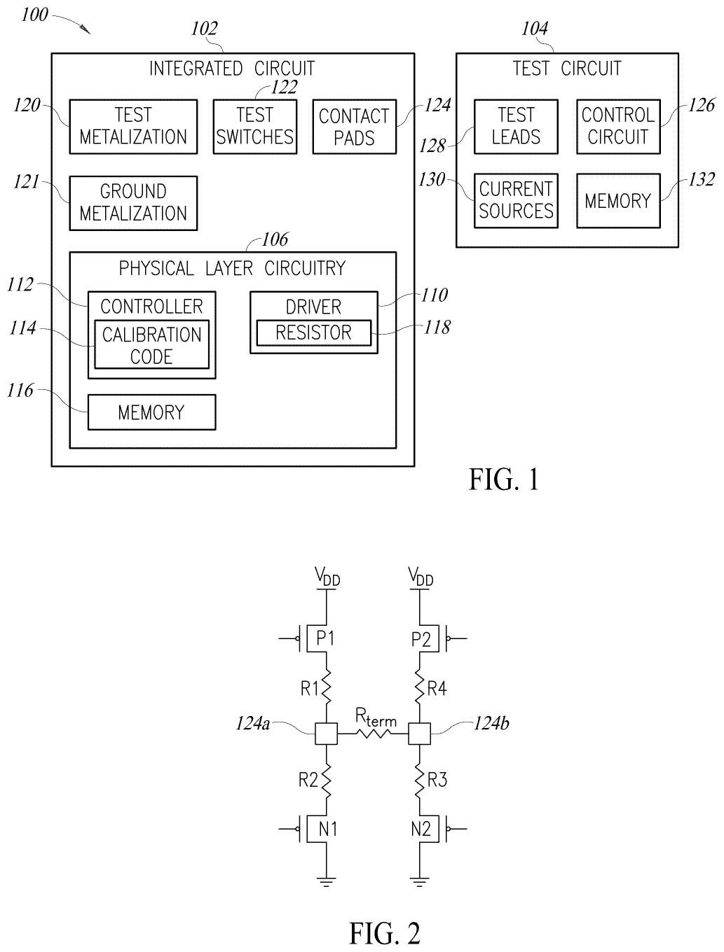

FIG. 1 is a block diagram of a system 100 including an integrated circuit 102 and a test circuit 104, according to one embodiment. As will be set forth in more detail below, the components of the integrated circuit 102 and the test circuit 104 cooperate to enable the test circuit 104 to effectively and efficiently calibrate a driver of the integrated circuit 102.

The integrated circuit 102 of FIG. 1 may be in a state prior to packaging of the integrated circuit 102. Prior to packaging of the integrated circuit 102, it is beneficial to test and calibrate aspects of the integrated circuit 102. In order to test the integrated circuit, contact pads 124 of the integrated circuit 102 are exposed so that the test circuit 104 can interface with the integrated circuit 102 for testing via the contact pads 124.

Prior to providing further description of the testing and calibration of the integrated circuit 102, it is beneficial to describe how the integrated circuit 102 may function after testing, calibration, and packaging of the integrated circuit 102. The integrated circuit 102 includes physical layer circuitry 106. After testing, calibration, and packaging of the integrated circuit 102, the physical layer circuitry 106 will implement a physical layer by which the integrated circuit 102 outputs data to a circuit external to the integrated circuit 102. The physical layer circuitry includes a driver 110, a controller 112, and a memory 116. The controller 112 controls the driver to drive data from the integrated circuit 102. The memory may store data that is output via the driver. The memory may also store software instructions associated with the controller 112.

After packaging of the integrated circuit 102, the integrated circuit 102 may be implemented in a high-speed point-to-point communication system according to an embodiment disclosed herein. In some embodiments, the system may include other types of high-speed communication systems. In the high-speed communication system, the integrated circuit 102 operates as a transmitter. The transmitter is coupled to a receiver via the differential connections. The differential connections may include a positive pad or terminal and a negative pad or terminal coupled to a load of the receiver.

In various embodiments, the controller 112 receives serial data by serial inputs and causes the driver 110 to drive the data to the receiver as a low voltage differential signal and converts it to a low voltage differential signal. In some embodiments, the serial data may be video data to be transmitted to a display. In this condition the positive and negative pads may be display ports.

The driver 110 may be a voltage driver of the transmitter configured to generate differential voltages from the received serial data under control of the controller 112. The transmitter operates in differential voltage mode transmission, which transmits the received serial data to a differential voltage in an output of the transmitter.

In low voltage applications, a low voltage supply in the transmitter provides an input voltage for the driver 110. In some examples, the input voltage may be in a range between 1 and 3 V.

A voltage variation of the low voltage input degrades the differential voltage swing specification. In a conventional high power transmission mode, a voltage regulator (e.g., low dropout regulator) may compensate the variation of the input voltage to meet the desired differential voltage swing. However, in low voltage applications, the voltage regulator may not efficiently compensate the variation of the low voltage supply due to burn power and voltage drop of the voltage regulator. In addition, usage of the voltage regulator increases complexity in the architecture of the driver 110, which consequently impacts return loss (e.g., by the impact of input capacitance of transmitter (CTX) and power consumption). Hence, in various embodiments disclosed herein, a different method than using the voltage regulator is used to compensate the voltage variation of the low voltage supply and control the differential voltage swing in the output of the transmitter.

In some embodiments, the driver 110 includes a resistor 108. The resistor 108 may be made up of a plurality of resistance blocks, resistance slices, or resistor paths coupled between the positive and negative contact pads. The differential voltage swing voltage is controlled by changing resistance value of the resistance blocks. For instance, a reduction of the low voltage supply may be compensated by modifying the resistance of the resistance blocks. In some embodiments, the resistance blocks may include slices of resistors, in which the number of slices coupled to the output of the transmitter is controlled by a plurality of switches. Each slice corresponds to an equivalent impedance which is coupled into the output of the driver 110 and are designed to match output impedance of the transmitter with a transmission line that is coupled to the output of the transmitter. In some embodiments, the slices of the resistors are voltage-dependent variable impedance. For instance, the voltage-dependent variable impedance may be plurality of NMOS or PMOS transistors. In various embodiments, the low voltage supply may change by ±20% while the differential voltage swing is changed by ±10%. In this condition, if the differential voltage swing increases, then a compensation technique may keep the differential voltage swing in an acceptable range. In various embodiments, the acceptable range of the differential voltage swing is about ±5%-10%. The low voltage supply may be about 0.8-1.2 V.

In various embodiments, an output impedance of the transmitter is designed to be matched with the impedance of the load. Impedance matching results in increased efficiency in power and data transmission. In contrast, an impedance mismatch between the transmitter and the load causes reflection wave and mode conversion of the transmission, which degrades power and data transmission. Further details regarding the physical layer circuitry 106 and high-speed data transmission can be found in U.S. provisional patent application No. 63/487,178, titled VOLTAGE COMPENSATION OF DIFFERENTIAL VOLTAGE SWING, filed on Feb. 27, 2023. U.S. provisional patent application No. 63/487,178 is incorporated herein by reference in its entirety.

The integrated circuit 102 includes a test metallization 120, a supply metallization, aground metallization 121, test switches 122 and contact pads 124. Two of the contact pads 124 may correspond to the positive and negative contact pads by which the driver 110 drives data when in operation. At the state shown in FIG. 102, the contact pads 124 may be exposed at an upper surface of the integrated circuit 102 such that the test circuit 104 can interface with the integrated circuit 102 for testing and calibration prior to packaging of the integrated circuit 102. The contact pads 124 can include contact pads utilized for various other functions of the integrated circuit 102.

The test metallization 102 corresponds to a metallization or other conductive structure that is exposed and accessible to the test circuit 104 prior to packaging. In one embodiment, the test metallization 120 may be exposed at the top of the integrated circuit 102 in a similar manner as the contact pads 124. In one embodiment, the test metallization 120 may extend into a dicing line of a wafer in which the integrated circuit 102 is incorporated prior to dicing and packaging of the integrated circuit 102.

In one embodiment, the test metallization 120 is no longer accessible after packaging of the integrated circuit. One benefit of utilizing the test metallization 120 rather than one of the contact pads 124 in the testing and calibration functions that will be described further below, is that valuable surface area of the integrated circuit 102 is not devoted to a test contact pad that will not be used after testing and calibration. Instead, all of the surface of the integrated circuit 102 can be devoted to contact pads 124 that will be utilized after testing, calibration, and packaging of the integrated circuit 102. The test metallization 120 may be implemented in a variety of forms without departing from the scope of the present disclosure.

The ground and supply metallization corresponds to a metallization or other conductive structure that is exposed and accessible to the test circuit 104 prior to packaging. The ground metallization 121 is connection of source of the NMOS to the ground of the integrated circuit. The supply metallization is a connection of a source of the PMOS to the supply of the integrated circuit. In one embodiment, the ground and supply metallization may be exposed at the top of the integrated circuit 102 in a similar manner as the contact pads 124. In one embodiment, the ground and supply metallization may extend into a dicing line of a wafer in which the integrated circuit 102 is incorporated prior to dicing and packaging of the integrated circuit 102.

In one embodiment, the ground and supply metallization 121 is no longer accessible after packaging of the integrated circuit.

The test switches 122 are switches that are implemented in the circuitry of the integrated circuit 102. The test switches 122 are utilized for testing and calibration of the integrated circuit 102. The test switches 122 may correspond to transistors formed within the integrated circuit 102.

In one embodiment, a first test switch 122 is coupled between the test metallization 120 and a first contact pad 124 of the driver 110. A second test switch 122 is coupled between the test metallization 120 and ground metallization of the driver 110. The first contact pad may correspond to a positive driver terminal of the driver 110. The second contact pad may correspond to a negative driver terminal of the driver 110. Opening the first switch of the test switches 122 electrically decouples the test metallization 120 from the first contact pad of the contact pads 124. Closing the first switch of the test switches 122 electrically couples (shorts) the test metallization 120 to the first contact pad of the contact pads 124. Opening the second switch of the test switches 122 electrically decouples the test metallization 120 from the ground metallization. Closing the second switch of the test switches 122 electrically couples (shorts) the test metallization 120 to the ground metallization.

The test circuit 104 may correspond to a circuit or system that tests and calibrates the integrated circuit 102. In one embodiment, the integrated circuit 102 is formed as one of a plurality of integrated circuits in a wafer. After processing of the wafer, and prior to dicing, the test circuit 104 may be utilized to test and calibrate each of the integrated circuits 102 of the wafer. The present description may focus primarily on the testing and calibration of the driver 110 by the test circuit 104. However, the test circuit 104 can also test and calibrate various other aspects of the integrated circuit 102.

The test circuit 104 includes a control circuit 126, a plurality of test leads 128, current sources 130, and the memory 132. Although not shown, the test circuit 104 may also include the voltage measuring circuits and other types of circuits. The control circuit 126 controls the functions of the test circuit 104. The control circuit 126 may perform impedance calculations based on the voltage measurements associated with the driver 110.

In one embodiment, impedance calibration can be done on any of the two pads. Due to the plurality of the structure of the driver, calibration done on any of the pads is valid for the other pad. Impedance calibration of an NMOS portion of the driver with resistance branches can be done between the first pad and the ground metallization. Impedance calibration of the PMOS portion of the driver with resistance branches can be done between the supply metallization and the first pad. Resistance blocks coupled to each of the positive pad and the negative pad are substantially symmetrical.

FIG. 2 is a schematic diagram of a driver coupled to two pads 124a and 124b. The first pad 124a may be considered a P-pad of the driver. The second pad 124b may be considered an N-pad of the driver. The first branch includes a first resistance block R1 coupled between an input voltage of the low voltage VDD supply described in FIG. 1 and the pad 124a. The first resistance block R1 includes one or more resistors coupled to the input voltage by a switch P1. The first branch also includes a second resistance block R2 coupled between ground and the pad 124a. The second resistance block R2 includes one or more resistors coupled to the ground by a switch N1. The state of the switch N1 is reversed or opposite to the state of the switch P1.

The second branch includes a third resistance block R3 coupled between the ground and the pad 124b. The third resistance block R3 may include one or more resistors coupled to the ground by a switch N2. The second branch also includes a fourth resistance block R4 coupled between the supply voltage VDD and the pad 124b. The fourth resistance block R4 may include one or more resistors coupled to the VDD by a switch P2. In various embodiments, the state of the switch P2 is reversed or opposite to the state of the switch N2. The pads 124a and 124b are coupled together by a resistance Rterm. In various embodiments, each of the resistance blocks R1-R4, includes variable resistances. The variable resistances may include a plurality of resistors coupled together by the switches N1, N2, P1, and P2. The switches may be metal oxide-semiconductor field-effect transistors (MOSFETs). Each of the resistors and MOSFETs form a slice. An equivalent resistance of each resistance block is a result of a combination of a plurality of slices. In FIG. 2, each resistance block is shown by a resistor schematic for simplicity, however, each resistor schematic represents the equivalent resistance of the respective plurality of slices coupled to the resistance block. More detail of the resistors and MOSFETs combination in slices are described in embodiments of Figures.

Returning to FIG. 1, in one embodiment, during testing and calibration, a first lead of the test leads 128 is coupled to the first driver contact pad of the contact pads 124. A second lead of the test leads 128 is coupled to the ground metalization 121. A third lead of the test leads 128 is coupled to the test metallization 120. Additional leads of the test circuit 104 may be coupled to contact pads corresponding to control terminals of the integrated circuit 102.

In one embodiment, the test circuit 104 initially applies a first driver calibration code to the integrated circuit 102. The first calibration code couples a plurality of resistive blocks, resistive slices, or some resistors of the resistor 118. In other words, the first calibration code couples certain resistances to take part in the overall resistor 118.

In one embodiment, after the first calibration code has been applied, the test circuit 104 drives a first test current through the resistor 118. In particular, the test current flows through the first lead of the test leads 128 to the first driver contact pad of the contact pads 124, through the resistor 118, to the ground metallization, through the second test lead of the test leads 128.

One possible solution to measure the impedance of the driver 110 is to simply measure the voltage drop across the driver 110 via the first and second test leads 128 while the first current is flowing through the resistor 118. However, this may result in an inaccurate measurement or calculation of the impedance of the driver 110 due to the contact impedance associated with the connection of the test leads 128 to the contact pads 124, and possibly due to other impedances associated with the test circuit 104. The overall impedance measurement of the driver 110 can erroneously include the impedances associated with the test leads 128 and other impedances of the test circuit 104.

In one embodiment, the test circuit 104 utilizes the test metallization 120 and the test switches 122, as well as multiple different tests currents to measure or calculate an impedance of the driver 110 that is not affected by impedances associated with the test circuit 104.

In one embodiment, while the test circuit 104 drives the first current through the driver 110, the test circuit 104 closes the first switch of the test switches 122, thereby shorting or coupling the test metallization 120 with the first driver contact pad of the contact pads 124. The test circuit 104 also opens the second switch of the test switches 122, thereby decoupling the test metallization 120 from the ground metallization. The opening and closing of the test switches 122 can be accomplished by providing control signals from the test circuit 104 to the integrated circuit 102 via contact pads 124 associated with providing commands or data to the integrated circuit 102. The test circuit 104 measures a first test voltage at the test metallization 120 while the first test switch is closed, the second test switch is open, and the first test current is flowing.

After measuring the first test voltage, the test circuit 104 opens the first test switch and closes the second test which, thereby decoupling the first driver contact pad from the test metallization 120 and coupling or shorting the ground metallization to the test metallization 120. The test circuit 104 then measures a second test voltage at the test metallization 120 while the first test switch is open, the second test which is closed, and the first current is flowing. After measuring the first and second test voltages, the test circuit 104 can measure or calculate a first voltage drop corresponding to the difference between the first test voltage and the second test voltage.

After measuring the first and second test voltages, the test circuit 104 drives a second test current through the driver 110 in the same manner as the first test current. The second test current has a different magnitude than the first test current. While the second test current is flowing, the test circuit 104 closes the first test switch 122, opens the second test switch 122, and measures a third test voltage of the test metallization 120. While the second test current is flowing, the test circuit 104 opens the first test switch 122, closes the second test switch 122, and measures a fourth test voltage of the test metallization 120. The test circuit 104 then calculates or measures a second voltage drop corresponding to the difference between the third test voltage and the fourth test voltage.

After calculating or measuring the first and second voltage drops, the test circuit 104 calculates the impedance of the driver 110. In one embodiment, the test circuit 104 calculates the impedance of the driver 110 based on the difference between the first and second voltage drops and based on the difference between the first and second test currents. In one embodiment, the test circuit 104 calculates the impedance Z of the driver 110 in accordance with the following formula:

$$Z = ( VD 1 - VD 2 ) / ( I 1 - I 2 ) ,$$

where VD1 is the first voltage drop, VD2 is the second voltage drop, I1 is the first test voltage, and I2 is the second test voltage. This calculation of the impedance Z of the driver 110 will not be affected by impedances associated with the test circuit 104. The test circuit 104 can calculate the impedance Z utilizing the test metallization 120 and test switches 122 in various other ways without departing from the scope of the present disclosure.

After the test circuit 104 calculates the impedance Z, the test circuit 104 compares the impedance Z to a reference impedance. The reference impedance may correspond to an expected impedance associated with a receiver circuit when the integrated circuit 102 is implemented in a high-speed data transmission system. In one embodiment, the reference impedance is 50 ohms, as this is a common standard impedance utilized in various communication systems, though other reference impedances can be utilized without departing from the scope of the present disclosure.

If the impedance Z matches the reference impedance within a selected tolerance, then calibration of the driver 110 is complete. If the impedance Z does not match the reference impedance within the selected tolerance, then the calibration of the driver 110 continues. In particular, the test circuit 104 applies a new calibration code to the driver 110. The new calibration code results in a different set of resistor paths, blocks, or slices coupled into the resistor 118. This causes the resistor 118 to have a different resistance than before. The test circuit 104 can then calculate the impedance Z of the driver 110 with the new calibration code utilizing the same procedure described above to initially measure the impedance Z. If the new impedance matches the reference impedance, the calibration is complete. If the new impedance does not match the reference impedance, then yet another calibration code is applied to the driver 110. This can continue until a calibration code is found that results in the impedance Z matching the reference impedance.

In one embodiment, after the correct calibration code has been found, the calibration code can be stored as a calibration code 114 in the memory 116. The controller 112 may continuously apply this calibration code 114 to the driver 110 during operation. Alternatively, the controller 112 does not store calibration code 114. Instead, the test circuit 104 makes final the calibration of the resistor 118 during calibration. Various schemes can be utilized to calibrate the resistor 118 of the driver 110 in order to achieve a desired impedance Z without departing from the scope of the present disclosure. The test circuit 104 can include other components, structures, and processes without departing from the scope of the present disclosure.

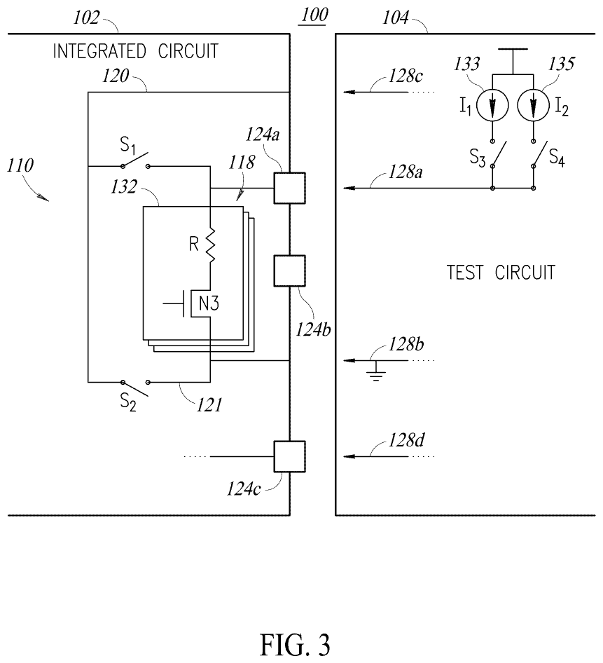

FIG. 3 is a partial schematic diagram of a system 100, according to one embodiment. The system 100 of FIG. 3 is one example is one example of the system 100 of FIG. 1. The partial view of the integrated circuit 102 illustrates some circuitry associated with the driver 110. In particular, the driver 110 includes a resistor 118 coupled between a first contact pad 124a and the ground metallization 121 of the integrated circuit 102. The first contact pad 124a may correspond to a positive driver pad of the driver 110. The second contact pad 124b may correspond to a negative driver pad of the driver 110.

The resistor 118 is made up of a plurality of parallel resistor paths 132. The parallel resistor paths 132 can each include a resistor R and a transistor N1. The parallel resistor paths 132 may also be called slices or blocks. The parallel resistor paths may have different resistances from each other. By selectively coupling or decoupling resistor paths 132 into the overall resistance 118 of the driver 110, the impedance of the driver 110 can be adjusted or calibrated. Each resistor path 132 can be coupled between the contact pads 124a and ground metallization via switches (not shown) that are either open or closed based on the calibration code. The driver 110 may include additional circuitry not shown in FIG. 2.

FIG. 3 also illustrates a test metallization 120 and switches S1 and S2. The switches S1 and S2 correspond to first and second test switches 122 described in relation to FIG. 1. The switches S1 and S2 can be controlled by the test circuit 104 during calibration via control terminals, such as the contact pad 124c and other contact pads.

The test circuit 104 includes a first lead 128a, a second lead 128b, a third lead 128c, and the fourth lead 128d. During testing and calibration, the lead 128a is brought into direct physical contact with the contact pad 124a, the lead 128b is brought into direct physical contact with the ground metallization. The lead 128c is brought into direct physical contact with the test metallization 120. The lead 128d is brought into physical contact with the contact pad 124c.

The test circuit 104 includes a current source 133 and a current source 135. The current source 133 generates a first test current I1 and can be selectively coupled to the lead 128a by third switch S3. The current source 135 generates a test current I2 and can be selectively coupled to the lead 128a by a fourth switch S4. The current sources 133 and 135 are coupled between a high supply voltage (e.g., VDD) and the switches S3 and S4, respectively. The lead 128b is coupled to ground. When the switch S3 is closed, the test circuit 104 drives the first test current I one through the lead 128a to the contact pad, through the resistor 118 of the driver 110, ground metallization, and to ground through the lead 128b. When the switch S4 is closed, the test circuit 104 drives the second test current I2 through the lead 128a to the contact pad, through the resistor 118 of the driver 110, ground metallization, and to ground through the lead 128b.

The test circuit 104 may also include a voltage measure or voltmeter coupled to the lead 128c. This enables the test circuit 1042 measure the voltage at the test metallization 120 via the lead 128c.

In one embodiment, in order to measure or calculate the impedance of the driver 110, the test circuit 104 drives the first test current I one through the driver 110 by closing the switch S3 and opening the switch S4. While the test circuit 104 drives the first current through the driver 110, the test circuit 104 closes the switch S1 and opens the switch S2, thereby shorting or coupling the test metallization 120 with the contact pad 124a and decoupling the test metallization 120 from the ground metallization. The test circuit 104 measures a first test voltage at the test metallization 120 while the switch S1 is closed, the switch S2 is open, and the first test current is flowing.

After measuring the first test voltage, the test circuit 104 opens the switch S1 and closes the switch S2, thereby decoupling the contact pad 124a from the test metallization 120 and coupling or shorting the ground metallization to the test metallization 120. The test circuit 104 then measures a second test voltage at the test metallization 120 while the switch S1 is open, the switch S2 is closed, and the first test current I1 is flowing. After measuring the first and second test voltages, the test circuit 104 can measure or calculating a first voltage drop VD1 corresponding to the difference between the first test voltage and the second test voltage.

After measuring the first and second test voltages, the test circuit 104 drives the second test current I2 through the driver 110 by opening the switch S3 and closing the switch S4. The second test current I2 has a different magnitude than the first test current I1. While the second test current I2 is flowing, the test circuit 104 closes the switch S1, opens the switch S2 and measures a third test voltage of the test metallization 120. While the second test current I2 is flowing, the test circuit 104 opens the switch S1, closes the second switch S2 and measures a fourth test voltage of the test metallization 120. The test circuit 104 then calculates or measures a second voltage drop VD2 corresponding to the difference between the third test voltage and the fourth test voltage.

After calculating or measuring the first and second voltage drops VD1, VD2, the test circuit 104 calculates the impedance of the driver 110. In one embodiment, the test circuit 104 calculates the impedance Z of the driver 110 in accordance with the following formula:

$$Z = ( VD 1 - VD 2 ) / ( I 1 - I 2 ) .$$

The test circuit 104 can calculate the impedance Z utilizing the test metallization 120 and test switches 122 in the various other ways without departing from the scope of the present disclosure.

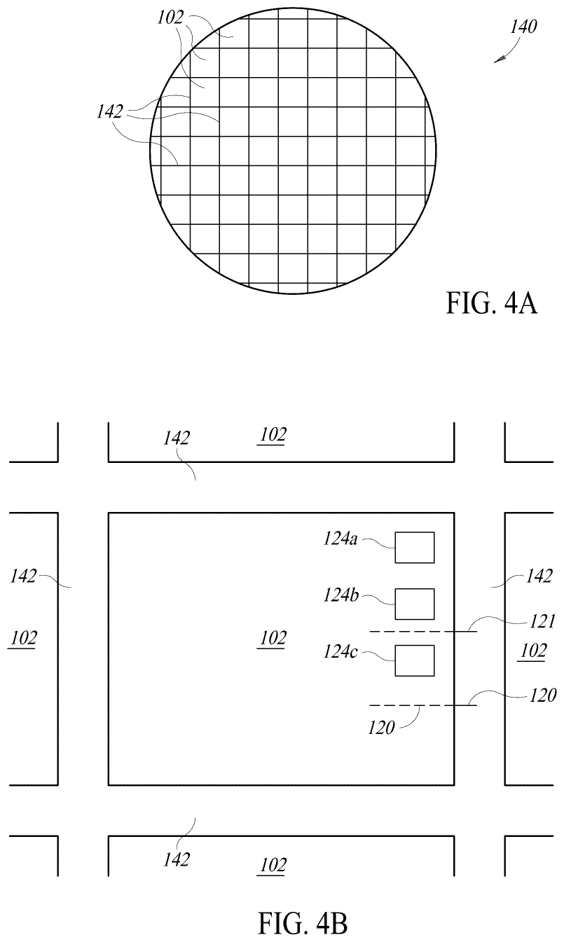

FIG. 4A is an illustration of a wafer 140, according to one embodiment. The wafer 140 may correspond to a semiconductor wafer in which a plurality of identical integrated circuits 102 have been formed. The integrated circuit 102 of FIGS. 1 and 3 may correspond to one of the integrated circuits 102 incorporated in the wafer 140 of FIG. 3A. Accordingly, the integrated circuits 102 of FIGS. 1 and 2 may be part of a wafer 140 prior to dicing. The wafer 140 includes dicing lines or scribe lines 142. The dicing lines 142 correspond to lines that delineate the integrated circuits 102 prior to dicing of the wafer 140. After the wafer 140 is diced, the integrated circuits 102 will be singulated from each other and can then be packaged. Testing and calibration of the driver 110 may be performed for each of the integrated circuits 102 by the test circuit 104 prior to dicing.

FIG. 4B is an enlarged view a portion of the wafer 140 of FIG. 3A, according to one embodiment. The enlarged view of FIG. 3B illustrates a central integrated circuit 102 surrounded by scribe lines 142. In particular, the scribe lines 142 separate the integrated circuit 102 from adjacent integrated circuits 102. The integrated circuit 102 includes contact pads 124a, 124b, and 124c. The integrated circuit 102 also includes a test metallization 120. The test metallization 120 protrudes into the scribe line 120. Said another way, a portion of the test metallization 120 is formed in the scribe lines 142. During testing and calibration, the leads 128 of the test circuit 142 physically contacts the contact pads 124a, 124b, and 124c and the test metallization 120. The test metallization 120 may, alternatively be formed and exposed at a different location on the integrated circuit 120.

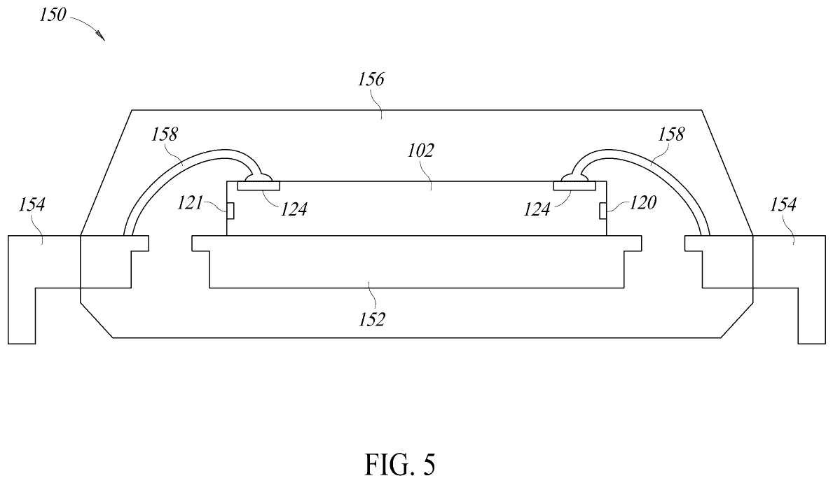

FIG. 5 is a cross-sectional view of an integrated circuit package 150, according to one embodiment. The integrated circuit 150 includes a lead frame including a pad 152 and leads 154. An integrated circuit 102, after testing, calibration, and dicing from the wafer 140, is placed on the pad 152. Bonding wires 158 are then formed providing electrical connection between the contact pads 124 and the leads 154. The integrated circuit 102 is then encapsulated by an encapsulant 156. The encapsulant can include an epoxy resin or other type of encapsulating material. After encapsulation, the contact pads 124 can be electrically accessed via the leads 154. However, the test metallization 120 is no longer accessible for electrical connection after the integrated circuit 102 has been encapsulated. Although FIG. 4 illustrates the test metallization 120 and the ground metalization 121 exposed at sides of the integrated circuit 102, in practice, the test metallization 120 and the ground metalization 121 may be exposed are located at another location on the integrated circuit 102 without departing from the scope of the present disclosure.

Although FIG. 5 illustrates an integrated circuit package 150 in which an integrated circuit 102 is placed on a die pad 152 and connected to leads 154 by wire bonds 158, other packaging types can be used. For example, an integrated circuit package can include solder bumps, solder balls, ball grid arrays, or other types of packaging and connecting schemes. Accordingly, the leads 154 are one example of electrical connectors of the integrated circuit package that can provide electrical connection to the contact pads 124. Alternatively, other types of electrical connectors can be utilized without departing from the scope of the present disclosure.

After the integrated circuit 102 has been packaged, the integrated circuit package 150 can be implemented in a communication system. In particular, the integrated circuit 102 can then be utilized to drive data as a transmitter to a receiver in a high-speed datalink as described in relation to FIG. 1.

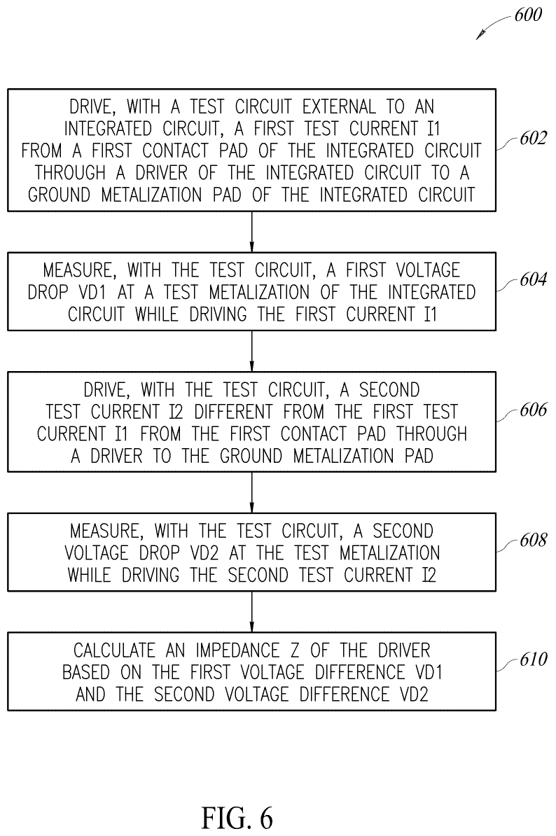

FIG. 6 is a flow diagram of a method 600, according to one embodiment. The method 600 can utilize components, systems, and processes described in relation to FIGS. 1-5. At 602, the method 600 includes driving, with a test circuit external to an integrated circuit, a first test current I1 from a first contact pad of the integrated circuit through a driver of the integrated circuit to a ground metallization of the integrated circuit. At 604, the method 600 includes measuring, with the test circuit, a first voltage drop VD1 at a test metalization of the integrated circuit while driving the first current I1. At 606, the method 600 includes driving, with the test circuit, a second test current I2 different from the first test current I1 from the first contact pad through a driver to the ground metallization. At 608, the method 600 includes measuring, with the test circuit, a second voltage drop VD2 at the test metalization while driving the second test current I2. At 610, the method 600 includes calculating an impedance Z of the driver based on the first voltage difference VD1 and the second voltage difference VD2.

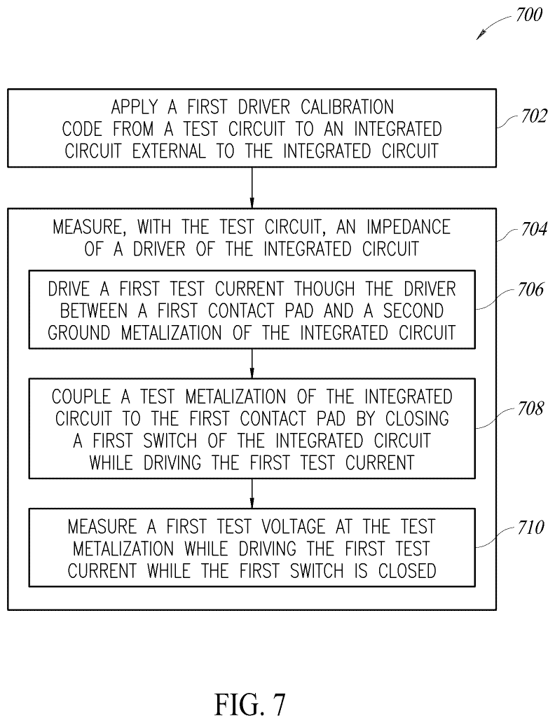

FIG. 7 is a flow diagram of a method 700, according to one embodiment. The method 700 can utilize components, systems, and processes described in relation to FIGS. 1-6. At 702, the method 700 includes applying a first driver calibration code from a test circuit to an integrated circuit external to the integrated circuit. At 704, the method 700 includes measuring, with the test circuit, an impedance of a driver of the integrated circuit. At 706, measuring the impedance of the driver includes driving a first test current through the driver between a first contact pad and a ground metallization of the integrated circuit. At 708, measuring the impedance of the driver includes coupling a test metalization of the integrated circuit to the first contact pad by closing a first switch of the integrated circuit while driving the first test current. At 710, measuring the impedance of the driver includes measuring a first test voltage at the test metalization while driving the first test current while the first switch is closed.

In one embodiment, a method includes driving, with a test circuit external to an integrated circuit, a first test current I1 from a first contact pad of the integrated circuit through a driver of the integrated circuit to a ground metallization of the integrated circuit. The method includes measuring, with the test circuit, a first voltage drop VD1 at a test metalization of the integrated circuit while driving the first current I1 and driving, with the test circuit, a second test current I2 different from the first test current I1 from the first contact pad through a driver to the ground metallization. The method includes measuring, with the test circuit, a second voltage drop VD2 at the test metalization while driving the second test current I2 and calculating an impedance Z of the driver based on the first voltage difference VD1 and the second voltage difference VD2.

In one embodiment, an integrated circuit package includes an integrated circuit die. The integrated circuit includes a first contact pad, a second contact pad, and a driver and configured to drive data from the integrated circuit via the first contact pad and the ground metalization and including a resistive path coupled between the first contact pad and the second contact pad. The integrated circuit includes a test metalization, a first switch coupled between the first contact pad and the test metalization, and a second switch coupled between the second contact pad and the test metalization.

In one embodiment, a method includes applying a first driver calibration code from a test circuit to an integrated circuit external to the integrated circuit and measuring, with the test circuit, an impedance of a driver of the integrated circuit. Measuring the impedance of the driver includes driving a first test current through the driver between a first contact pad and a ground metallization of the integrated circuit, coupling a test metalization of the integrated circuit to the first contact pad by closing a first switch of the integrated circuit while driving the first test current, and measuring a first test voltage at the test metalization while driving the first test current while the first switch is closed.

In one embodiment, a test circuit includes a first lead, a second lead, a third lead, and a control circuit. The control circuit is configured to drive a first test current between the first lead and the second lead through a driver of an integrated circuit via a first contact pad of the integrated circuit coupled to the first lead and a ground metallization of the integrated circuit coupled to the second lead. The control circuit is configured to couple a test metalization of the integrated circuit to the first contact pad by closing a first switch of the integrated circuit while driving the first test current. The control circuit is configured to measure, with the third lead, a first test voltage at the test metalization while driving the first test current while the first switch is closed. The control circuit is configured to calculate an impedance of the driver based on the first test voltage.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
driving, with a test circuit external to an integrated circuit, a first test current I1 from a first contact pad of the integrated circuit through a driver of the integrated circuit to a ground metallization of the integrated circuit;
measuring, with the test circuit, a first voltage drop VD1 at a test metalization of the integrated circuit while driving the first current I1;
driving, with the test circuit, a second test current I2 different from the first test current I1 from the first contact pad through a driver to the ground metallization;
measuring, with the test circuit, a second voltage drop VD2 at the test metalization while driving the second test current I2; and
calculating an impedance Z of the driver based on the first voltage difference VD1 and the second voltage difference VD2.

2. The method of claim 1, comprising calculating the impedance Z based on the first voltage drop VD1, the second voltage drop VD2, the first test current I1, and the second test current I2.

3. The method of claim 2, comprising calculating the impedance Z with the formula Z=(VD1−VD2)/(I1−I2).

4. The method of claim 3, wherein measuring the first voltage value includes, while driving the first test current:
closing a first switch of the integrated circuit coupled between the test metalization and the first contact pad;
opening a second switch of the integrated circuit coupled between the test metalization and the ground metallization;
measuring a first test voltage at the test metalization while the first switch is closed and the second switch is open;
opening the first switch;
closing the second switch; and
measuring a second test voltage at the test metalization while the first switch is open and the second switch is closed, wherein the first voltage drop VD1 is a difference between the first test voltage and the second test voltage.

5. The method of claim 4, wherein measuring the second voltage drop VD2 includes, while driving the second test current:
closing the first switch;
opening the second switch;
measuring a third test voltage at the test metalization while the first switch is closed and the second switch is open;
opening the first switch;
closing the second switch; and
measuring a fourth test voltage at the test metalization while the first switch is open and the second switch is closed, wherein the second voltage drop VD2 is a difference between the third test voltage and the fourth test voltage.

6. The method of claim 1, comprising, after calculating the impedance:
comparing the impedance Z to a reference impedance;
if the impedance Z matches the reference impedance, stopping an impedance calibration process of the driver;
if the impedance Z does not match the reference impedance:
adjusting a resistor of the driver; and
calculating the impedance Z of the driver a second time after adjusting the resistor.

7. The method of claim 6, wherein the resistor includes a plurality of resistance paths that can each be selectively coupled or decoupled from contributing to the impedance Z of the driver.

8. The method of claim 7, wherein adjusting the impedance includes coupling or decoupling one or more of the resistance paths from contributing to the impedance Z of the driver.

9. The method of claim 1, comprising:
calculating the impedance Z while the integrated circuit is incorporated in a wafer that includes a plurality of integrated circuit; and
dicing the integrated circuit form the wafer after calculating the impedance Z.

10. The method of claim 9, wherein after dicing and packaging the integrated circuit, the test metalization cannot be electrically accessed by circuits external to the integrated circuit.

11. An integrated circuit package comprising:
an integrated circuit die including:
a first contact pad;
a second contact pad;
a driver and configured to drive data from the integrated circuit via the first contact pad and the ground metalization and including a resistive path coupled between the first contact pad and the ground metallization;
a test metalization;
a first switch coupled between the first contact pad and the test metalization; and
a second switch coupled between the ground metallization and the test metalization.

12. The integrated circuit package of claim 11, wherein the driver includes a plurality of resistors that can be selectively coupled or decoupled from the resistive path.

13. The integrated circuit package of claim 12 comprising a controller configured to control the driver.

14. The integrated circuit package of claim 13, wherein the controller is configured to store a calibration code that controls which resistors are coupled into the resistive path.

15. The integrated circuit package of claim 13, wherein the controller and the driver make up a physical layer of the integrated circuit.

16. The integrated circuit package of claim 11, comprising:
a molding compound encapsulating the integrated circuit die; and
a plurality of electrical connectors, wherein the first contact pad and the second contact pad are electrically connected to respective electrical connectors, wherein the test metalization is not electrically connected to a respective electrical connector.

17. A method, comprising:
applying a first driver calibration code from a test circuit to an integrated circuit external to the integrated circuit; and
measuring, with the test circuit, an impedance of a driver of the integrated circuit, by:
driving a first test current through the driver between a first contact pad and a ground metallization of the integrated circuit;
coupling a test metalization of the integrated circuit to the first contact pad by closing a first switch of the integrated circuit while driving the first test current; and
measuring a first test voltage at the test metalization while driving the first test current while the first switch is closed.

18. The method of claim 17, comprising:
comparing the impedance to a reference impedance;
if the impedance matches the reference impedance, stopping a calibration process of the driver; and
if the impedance does not match the reference impedance, applying a second driver calibration code to the integrated circuit.

19. The method of claim 17, wherein measuring the impedance includes, while driving the first current:
opening the first switch;
coupling the test metalization to the ground metallization by closing a second switch of the integrated circuit; and
measuring a second test voltage at the test metalization while the first switch is open and the second switch is closed.

20. The method of claim 19, wherein measuring the impedance includes:
driving, with the test circuit, a second test current different than the first test current through the driver between the first contact pad and ground metallization; and
while driving the second test current:
measuring a third test voltage at the test metalization while the first switch is closed and the second switch is open; and
measuring a fourth test voltage at the test metalization while the first switch is open and the second switch is closed.

21-24. (canceled)
